(19) United States
(12) Patent Application Publication
(10) Pub. No.: US 2026/0271597 A1
(43) Pub. Date: Sep. 10, 2026

(54) DISPLAY PANEL AND DISPLAY DEVICE

(71) Applicant: Wuhan Tianma Microelectronics Co., Ltd., Wuhan (CN)

(72) Inventors: Shihao TANG, Wuhan (CN); Yang ZENG, Wuhan (CN); Shouzheng WU, Wuhan (CN); Ming YANG, Wuhan (CN)

(73) Assignee: Wuhan Tianma Microelectronics Co., Ltd., Wuhan (CN)

(21) Appl. No.: 18/869,546

(22) PCT Filed: Aug. 19, 2022
(86) PCT No.: PCT/CN2022/113741

§ 371 Date: Nov. 26, 2024

(30) Foreign Application Priority Data
Jul. 25, 2022 (CN) 202210877776.6

(51) Int. Cl. H10K 59/80; H10K 59/38

(52) U.S. Cl. CPC H10K 59/8792; H10K 59/38

(57) ABSTRACT

A display panel and a display device are provided. The display panel includes a display area, and the display area includes a first display sub-area and a second display sub-area having a light transmission area. The display area includes light-emitting devices and color resists, and the color resists are located at a side of the light-emitting devices facing the light-emitting surface of the display panel. A thickness of at least part of the color resists in the second display sub-area is greater than thicknesses of the color resists in the first display sub-area. The reflectivity difference between the second display sub-area and the first display sub-area is reduced, which ensures the display uniformity of the display panel, and also avoids the problem that the second display sub-area is obviously visible due to the large reflectivity difference between the second display sub-area and the first display sub-area.

### CROSS-REFERENCE TO RELATED APPLICATIONS

The present application is a National Phase of International Application No. PCT/CN2022/113741, filed on Aug. 19, 2022, which claims priority to Chinese Patent Application No. 202210877776.6, filed on Jul. 25, 2022, the entire contents of which are incorporated herein by reference.

### TECHNICAL FIELD

The present disclosure relates to the field of display technologies, and in particular, to a display panel and a display device.

### BACKGROUND

With the continuous development of display technologies, full-screen has become a mainstream display screen design, which has an ultra-high screen-to-body ratio. In order to make the display screen have a high screen-to-body ratio, the CUP (camera under panel) technology has been concerned by more and more manufacturers. In the CUP technology, the optical devices such as cameras provide on the back of the display area of the display screen, and the area where these cameras and optical sensors are arranged is referred to as the CUP area. It can be seen that the CUP area can not only display images, but also transmit light required by the cameras. How to improve the light transmittance of the CUP area and ensure the display uniformity between the CUP and the conventional display is an urgent problem to be solved.

### SUMMARY

In view of this, a display panel and a display device are provided in embodiments of the present disclosure to solve the above problems.

In one aspect, the present disclosure provides a display panel having a display area. The display area includes a first display sub-area and a second display sub-area, and the second display sub-area includes a light transmission area. The display area is provided with a light-emitting device layer and a color resist layer, the light-emitting device layer includes a plurality of light-emitting devices, the color resist layer includes a plurality of color resists, and the color resists are located at a side of the light-emitting devices facing a light-emitting surface of the display panel. A thickness of at least part of the color resists in the second display sub-area is greater than that of the color resists in the first display sub-area.

In another aspect, the present disclosure provides a display device including the display panel according to the first aspect.

In an embodiment of the present disclosure, the thickness of at least part of the color resists in the second display sub-area is controlled to be greater than that of the color resists in the first display sub-area, such that the transmittance of the color resists in the second display sub-area to the external light can be reduced, and the amount of light that can be reflected in the second display sub-area can be reduced. As a result, the reflectivity of the sub-pixel area in the second display sub-area to the external light can be less than that of the sub-pixel area in the first display sub-area to the external light. According to the technical solutions of the present disclosure, the reflectivity difference between the second display sub-area and the first display sub-area can be reduced, which ensures the display uniformity of the display panel, and also avoids the problem that the second display sub-area is obviously visible due to a larger reflectivity difference between the second display sub-area and the first display sub-area.

### BRIEF DESCRIPTION OF DRAWINGS

In order to more clearly describe the technical solutions of embodiments of the present disclosure, the following briefly describes the drawings desired in the embodiments. It is appreciated that, the drawings described below are merely some embodiments of the present disclosure, and for those skilled in the art, other drawings can be obtained based on these drawings without creative effort.

FIG. 1 is a schematic diagram of a display panel provided by an embodiment of the present disclosure;

FIG. 2 is a schematic diagram of a display panel provided by an embodiment of the present disclosure;

FIG. 3 is a schematic cross-sectional view taken along a direction MM′ in FIGS. 1 and 2;

FIG. 4 is a partial schematic diagram of a CC area in the dashed box in FIGS. 1 and 2;

FIG. 5 is a schematic cross-sectional view taken along a direction NN′ in FIG. 4;

FIG. 6 is a schematic cross-sectional view taken along a direction NN′ in FIG. 4;

FIG. 7 is a schematic diagram of an arrangement of color resists in a display panel provided by an embodiment of the present disclosure;

FIG. 8 is a schematic diagram of an arrangement of color resists in a display panel provided by an embodiment of the present disclosure;

FIG. 9 is a schematic diagram of an arrangement of color resists in a display panel provided by an embodiment of the present disclosure;

FIG. 10 is a schematic diagram of an arrangement of color resists in a display panel provided by an embodiment of the present disclosure;

FIG. 11 is a schematic diagram of an arrangement of color resists in a display panel provided by an embodiment of the present disclosure;

FIG. 12 is a partial cross-sectional view of a display panel provided by an embodiment of the present disclosure;

FIG. 13 is a partial cross-sectional view of a second display sub-area in a display panel provided by an embodiment of the present disclosure;

FIG. 14 is a partial cross-sectional view of a second display sub-area in a display panel provided by an embodiment of the present disclosure;

FIG. 15 is a schematic structural diagram of color resists and an auxiliary layer in a display panel provided by an embodiment of the present disclosure;

FIG. 16 is a partial cross-sectional view of a display panel provided by an embodiment of the present disclosure;

FIG. 17 is a schematic projection diagram of a touch layer in a display panel provided by an embodiment of the present disclosure;

FIG. 18 is a partial cross-sectional view of a display panel provided by an embodiment of the present disclosure;

FIG. 19 is a partial cross-sectional view of a second display sub-area in a display panel provided by an embodiment of the present disclosure;

FIG. 20 is a partial cross-sectional view of a display panel provided by an embodiment of the present disclosure;

FIG. 21 is a partial cross-sectional view of a display panel provided by an embodiment of the present disclosure;

FIG. 22 is a partial cross-sectional view of a display panel provided by an embodiment of the present disclosure;

FIG. 23 is a partial cross-sectional view of a display panel provided by an embodiment of the present disclosure; and

FIG. 24 is a schematic diagram of a display device provided by an embodiment of the present disclosure.

### DESCRIPTION OF EMBODIMENTS

In order to better understand technical solutions of the present disclosure, the embodiments of the present disclosure are described in details with reference to the drawings.

It should be clearly understood that the described embodiments are merely some, rather than all, of the embodiments of the present disclosure. All other embodiments obtained by a person of ordinary skill in the art based on the embodiments of the present disclosure shall fall within the protection scope of the present disclosure.

The terms used in the embodiments of the present disclosure are just for the purpose of describing specific embodiments, and are not intended to limit the present disclosure. The terms “a”, “an”, “the” and “said” in a singular form in the embodiments of the present disclosure and the attached claims are also intended to include plural forms thereof, unless explicitly noted otherwise in the context.

It should be understood that the term “and/or” used herein is merely an association relationship describing an associated object, and indicates that there may be three relationships. For example, A and/or B may indicate three situations: A alone, both A and B, and B alone. In addition, the character “/” herein generally indicates an “or” relationship between the associated objects.

In the description of the present disclosure, it should be understood that the terms such as “substantially”, “approximate to”, “approximately”, “about”, “roughly”, and “in general” described in the claims and the embodiments of the present disclosure mean general agreement within a reasonable process operation range or tolerance range, rather than an exact value.

It should be understood that although terms such as first, second, and third may be used to describe directions in the embodiments of the present disclosure, these directions should not be limited to these terms. These terms are used only to distinguish such as directions from each other. For example, without departing from the scope of the embodiments of the present disclosure, a first direction may also be referred to as a second direction, and similarly, a second direction may also be referred to as a first direction.

Through careful and in-depth research, the embodiments of the present disclosure provide a solution for the problems existing in the related art.

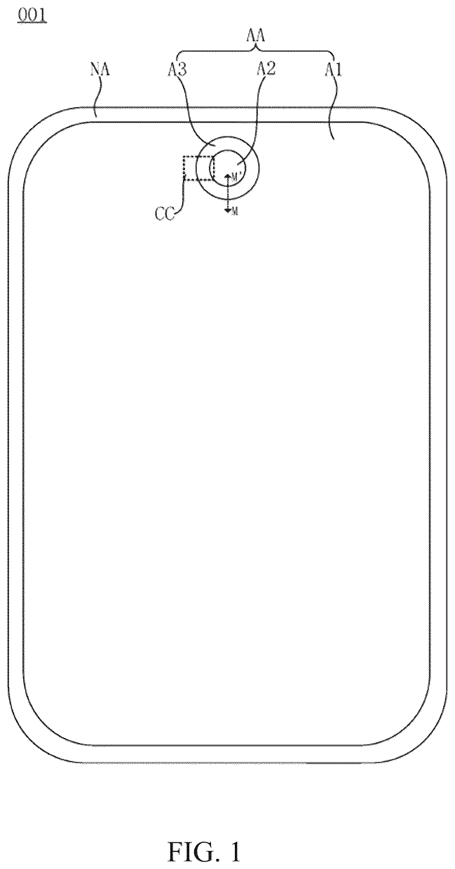

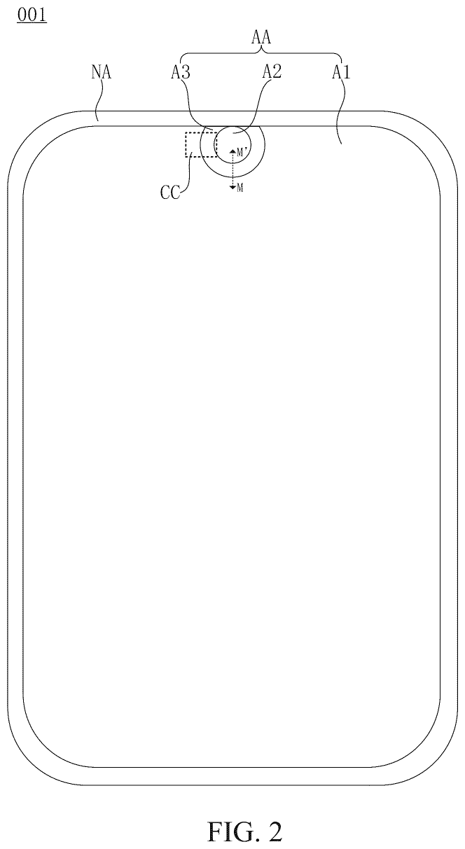

FIG. 1 is a schematic diagram of a display panel provided by an embodiment of the present disclosure. FIG. 2 is a schematic diagram of a display panel provided by an embodiment of the present disclosure.

An embodiment of the present disclosure provides a display panel. As shown in FIG. 1 and FIG. 2, the display panel 001 includes a display area AA and a non-display area NA. The non-display area NA surrounds the display area AA. The display area AA is a main area for light-emitting display. The non-display area NA is mainly configured for providing an encapsulation structure, a peripheral circuit, a peripheral signal line, and the like.

The display area AA includes a first display sub-area A1 and a second display sub-area A2. Light transmittance of the first display sub-area A1 is less than that of the second display sub-area A2. The first display sub-area A1 and the second display sub-area A2 are different areas in the display area AA. The transmittance of the second display sub-area A2 to external light is greater than that of the first display sub-area A1. In addition, the first display sub-area A1 may at least partially surround the second display sub-area A2.

The second display sub-area A2 has higher transmittance to external light. Thus, the region where the second display sub-area A2 is located may be used to provide an optical functional element. For example, a device integrated with an optical sensor, such as a camera and a fingerprint identification structure may be provided below the second display sub-area A2. In addition to the function of light-emitting display, the second display sub-area A2 may further implement an optical signal transmission function, for example, at least one of functions such as photographing and biometric recognition.

As shown in FIG. 1, the first display sub-area A1 may completely surround the second display sub-area A2. As shown in FIG. 2, the first display sub-area A1 may also partially surround the second display sub-area A2. Of course, the second display sub-area A2 may be in any shape of one of a circle, an ellipse, and a rectangle.

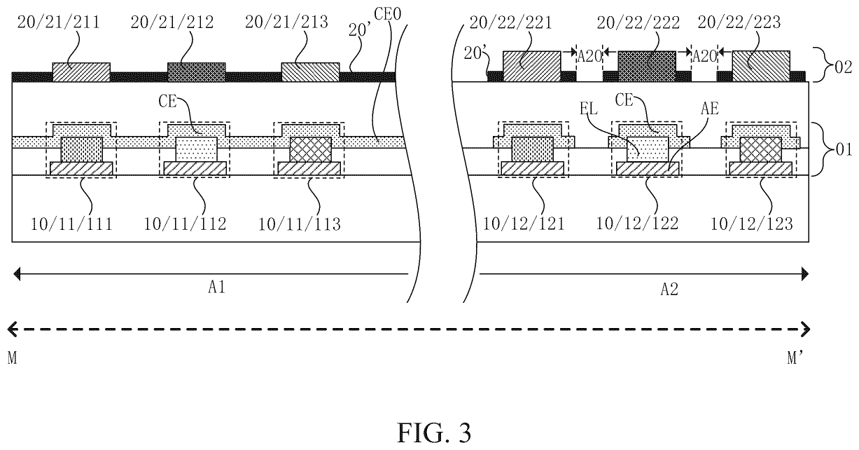

FIG. 3 is a cross-sectional view taken along a direction MM′ in FIGS. 1 and 2.

The display area AA of the display panel 001 includes a substrate, a circuit array layer (not shown in FIG. 3) provided at a side of the substrate, a light-emitting device layer 01, and a color resist layer 02. The circuit array layer includes a plurality of pixel circuits (not shown in FIG. 3, referring to the following drawings). The light-emitting device layer 01 includes a plurality of light-emitting devices 10. The pixel circuits provide light-emitting signals for the light-emitting devices 10. The color resist layer 02 includes a plurality of color resists 20 and a black matrix 20′ surrounding the color resists 20. The color resists 20 are provided at a side of the light-emitting devices 10 facing a light-emitting surface of the display panel 001. The color resists 20 may filter light emitted by the light-emitting devices 10, making chromaticity of the light emitted by the light-emitting devices 10 purer when it is emitted from the display panel 001.

In an embodiment of the present disclosure, a thickness of at least part of the color resists 20 in the second display sub-area A2 is greater than that of the color resists 20 in the first display sub-area A1. As shown in FIG. 3, the color resists 20 in the first display sub-area A1 are marked as the color resists 21, and the color resists 20 in the second display sub-area A2 are marked as the color resists 22, so that the thickness of at least part of the color resists 22 is greater than that of the color resists 21.

In addition, as shown in FIG. 3, the first display sub-area A1 includes a first-color color resist 211, a second-color color resist 212 and a third-color color resist 213, and the second display sub-area A2 includes a first-color color resist 221, a second-color color resist 222 and a third-color color resist 223. The first-color color resist 211 is provided at a side of the first color light-emitting device 111 facing the light-emitting surface of the display panel 001, the second-color color resist 212 is provided at a side of the second color light-emitting device 112 facing the light-emitting surface of the display panel 001, and the third-color color resist 213 is provided at a side of the third color light-emitting device 113 facing the light-emitting surface of the display panel 001. The first-color color resist 221 is provided at a side of the first color light-emitting device 121 facing the light-emitting surface of the display panel 001, the second-color color resist 222 is provided at a side of the second color light-emitting device 122 facing the light-emitting surface of the display panel 001, and the third-color color resist 223 is provided at a side of the third color light-emitting device 123 facing the light-emitting surface of the display panel 001. The thickness of the color resists 22 of at least one color in the second display sub-area A2 is greater than that of the color resists 21 of the same color in the first display sub-area A1. For example, as shown in FIG. 3, the thickness of the first-color color resist 221 is greater than the thickness of the first-color color resist 211, the thickness of the second-color color resist 222 is greater than the thickness of the second-color color resist 212, and the thickness of the third-color color resist 223 is greater than the thickness of the third-color color resist 213.

As shown in FIG. 3, the light-emitting device 10 may be an organic light-emitting diode, including a cathode CE, an anode AE, and a light-emitting material layer EL provided between the cathode CE and the anode AE. The value of the electric field between the cathode CE and the anode AE controls the light-emitting brightness of the light-emitting material layer EL. In order to ensure that each light-emitting device 10 can emit light with different brightness, the anode AE of each light-emitting device 10 may be electrically connected to different pixel circuits, and the cathodes CE of the plurality of light-emitting devices 10 may be electrically connected to each other and all located in the cathode layer CE0.

Referring to FIG. 3, the color resist layer 02 includes a black matrix 20′ and color resists 20 surrounded by the black matrix 20′. It could be understood that, when the film layer where the black matrix 20′ is located is prepared, hollow portions for filling the color resists 20 is reserved, the reserved hollow portions overlap with the light-emitting devices 10 correspondingly, and the color resists 20 are filled in the hollow portions to implement that the black matrix 20′ surrounds the color resists 20.

In addition, in an embodiment, the black matrix 20′ is provided between the color resists 20. In order to achieve high light transmittance of the second display sub-area A2, the black matrix 20′ in the second display sub-area A2 is usually designed to include openings, so that the black matrix 20′ in the second display sub-area A2 remains only a small part which surrounds the color resists 20. That is, the second display sub-area A2 has a light-transmitting area A20. The light-transmitting area A20 corresponds to a area of the black matrix 20′ where the openings are located. It should be noted that the light-transmitting area A20 does not overlap with the light-emitting devices 10. The device integrated with an optical sensor below the second display sub-area A2 may specifically collect light from the external or emit light to the external through the light-transmitting area A20.

The light-transmitting area A20 in the second display sub-area A2 may expose a larger area of the cathode layer CE0. The cathode layer CE0 generally adopts a magnesium-silver material capable of reflecting light, so that the reflectivity of the second display sub-area A2 to external light can be increased. In order to solve the above problems, the cathode layer CE0 in the second display sub-area A2 is usually designed patterned. That is, the cathode layer CE0 in the second display sub-area A2 is designed hollowed, and the hollowed position of the cathode layer CE0 does not overlap with the light-emitting devices 10.

It should be noted that the cathode layer CE0 in the first display sub-area A1 may have an entire continuous structure. A area between adjacent color resists 20 in the first display sub-area A1 is completely filled with the black matrix 20′.

The reflectivity of the second display sub-area A2 to the external light is verified under two conditions: whether the cathode layer CE0 in the second display sub-area A2 is patterned or not. When the cathode layer CE0 in the second display sub-area A2 is not patterned, the reflectivity of the second display sub-area A2 to the external light is 12%. When the cathode layer CE0 in the second display sub-area A2 is patterned, the reflectivity of the second display sub-area A2 to the external light is 6%. It can be seen that the patterning design of the cathode layer CE0 in the second display sub-area A2 can indeed reduce the reflectivity of the second display sub-area A2 to external ambient light, but the improvement effect thereof is limited.

It have been found that except for the reflection of the external light by the cathode layer CE0, an area with a larger reflectivity to the external light in the second display sub-area A2 comes from the sub-pixel area, that is, comes from the area where the color resists 20 are located.

In an embodiment of the present disclosure, by setting the thickness of at least part of the color resists 20 in the second display sub-area A2 greater than that of the color resists 20 in the first display sub-area A1, the transmittance of the color resists 20 in the second display sub-area A2 to external light can be reduced, thereby reducing the light emitted through the color resists 20 into the film layer where the light-emitting devices are located 10 and the film layer where the pixel circuits are located in the display panel 001. That is, by setting a larger thickness of the color resists 20 in the second display sub-area A2, the amount of light that can be reflected in the second display sub-area A2 can be reduced, and thus the reflectivity of the sub-pixel area in the second display sub-area A2 to the external light can be smaller than the reflectivity of the sub-pixel area in the first display sub-area A1 to the external light. Therefore, in the technical solution of the present disclosure, the reflectivity difference between the second display sub-area A2 and the first display sub-area A1 is reduced, which ensures the display uniformity of the display panel 001, and also avoids the problem that the second display sub-area A2 is obviously visible due to the larger reflectivity difference between the second display sub-area A2 and the first display sub-area A1.

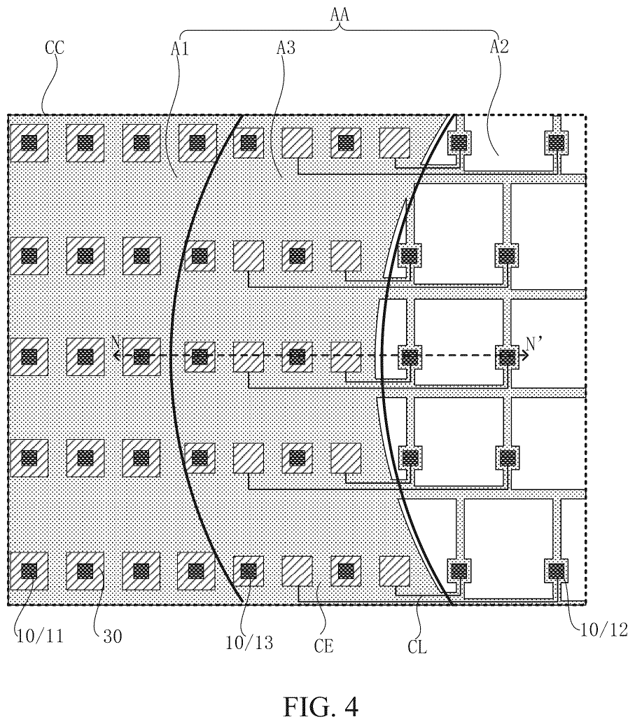

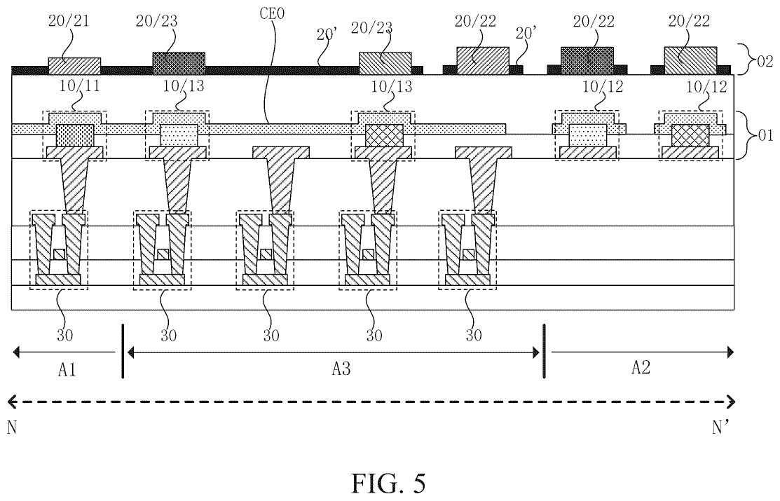

FIG. 4 is a partial schematic diagram of a CC area in a dashed box in FIG. 1 and FIG. 2. FIG. 5 is a schematic cross-sectional view along a direction NN′ in FIG. 4.

In an embodiment of the present disclosure, as shown in FIG. 1 and FIG. 2, the display area AA further includes a third display sub-area A3. The third display sub-area A3 is located between the first display sub-area A1 and the second display sub-area A2. In addition, transmittance of the third display sub-area A3 is less than that of the second display sub-area A2.

In an implementation, the third display sub-area A3 may also include a light-transmitting area A20. In a unit area, an area of the light-transmitting area A20 in the third display sub-area A3 is less than that of the light-transmitting area A20 in the second display sub-area A2.

In an implementation, the third display sub-area A3 does not include the light-transmitting area A20.

As shown in FIG. 4 and FIG. 5, a plurality of pixel circuits 30 and a plurality of light-emitting devices 10 are provided in the third display sub-area A3. A part of the pixel circuits 30 in the third display sub-area A3 may be electrically connected to the light-emitting devices 10 in the second display sub-area A2 via a connection electrode CL. The light-emitting devices 10 in the third display sub-area A3 are electrically connected to the pixel circuits 30 in the third display sub-area A3. That is, the pixel circuits 30 electrically connected to at least part of the light-emitting devices 10 in the second display sub-area A2 are arranged in the third display sub-area A3 to increase the light transmittance of the second display sub-area A2.

In addition, the pixel circuits 30 in the first display sub-area A1 may be electrically connected to the light-emitting devices 10 in the first display sub-area A1, and the light-emitting devices 10 in the first display sub-area A1 may be electrically connected to the pixel circuits in the first display sub-area A1.

Furthermore, the cathode layer CE0 in the third display sub-area A3 may also have an entire continuous structure. A area between adjacent color resists 20 in the third display sub-area A3 is filled with the black matrix 20′.

In an embodiment, as shown in FIG. 5, the thickness of the color resists 20 in the third display sub-area A3 is greater than that of the color resists 20 in the first display sub-area A1, and less than that of the color resists 20 in the second display sub-area A2. As shown in FIG. 5, the color resists 20 in the third display sub-area A3 are marked as the color resists 23, so that the thickness of the color resists 23 is greater than that of the color resists 21, and the thickness of the color resists 23 is less than that of the color resists 22.

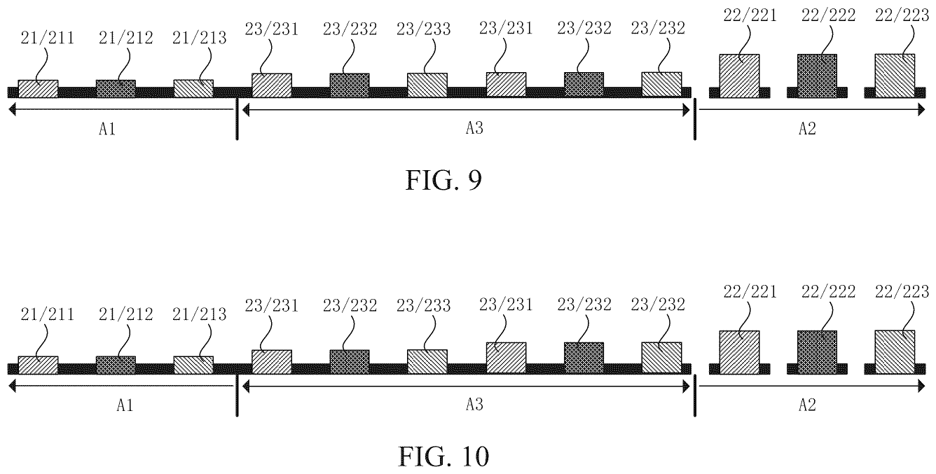

In addition, as shown in FIG. 5, and in combination with FIG. 9 or FIG. 10, the third display sub-area A3 includes a first-color color resist 231, a second-color color resist 232 and a third-color color resist 233. The thickness of the color resists 23 of any color in the third display sub-area A3 is greater than that of the color resists 21 of the same color in the first display sub-area A1 and less than that of the color resists 22 of the same color in the second display sub-area A2. For example, as shown in FIG. 3, the thickness of the first-color color resist 231 is less than that of the first-color color resist 221 and greater than that of the first-color color resist 211, the thickness of the second-color color resist 232 is less than that of the second-color color resist 222 and greater than that of the second-color color resist 212, and the thickness of the third-color color resist 233 is less than that of the third-color color resist 223 and greater than that of the third-color color resist 213.

In this embodiment, the thickness of the color resists 23 in the third display sub-area A3 is greater than that of the color resists 21 in the first display sub-area A1 and less than that of the color resists 22 in the second display sub-area A2, so that the reflectivity of the sub-pixel area in the third display sub-area A3 to external light is less than that of the sub-pixel area in the first display sub-area A1 to external light, and the reflectivity of the sub-pixel area in the third display sub-area A3 to external light is greater than that of the sub-pixel area in the second display sub-area A2 to external light. Therefore, a transition display area is formed between the first display sub-area A1 and the second display sub-area A2. When the display panel 001 performs light-emitting display, the third display sub-area A3 is arranged to make the visual connection between the display sub-areas in the display area AA more natural, so that the obtrusive feeling of display image quality is avoided, and the area with larger reflectivity difference is prevented from being obviously visible to the user.

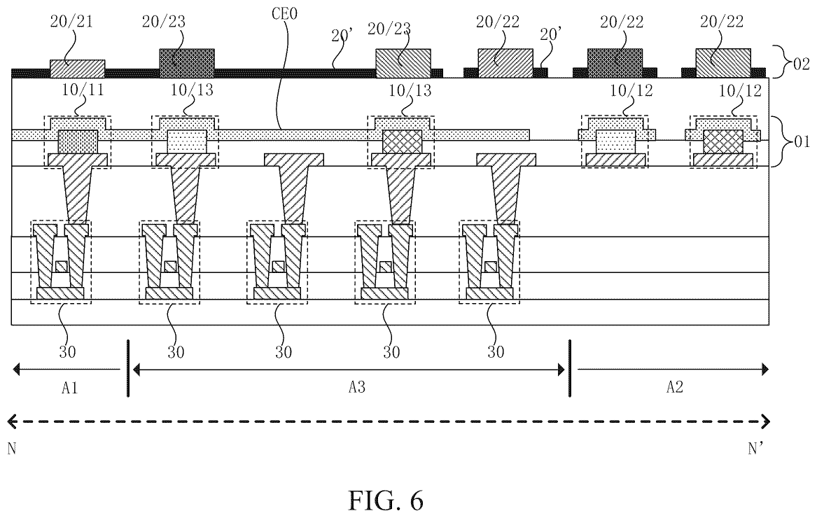

FIG. 6 is a schematic cross-sectional view along a direction NN′ in FIG. 4.

In an embodiment, the thickness of the color resists 20 in the third display sub-area A3 is the same as that of the color resists 20 in the second display sub-area A2. That is, the thickness of the color resists 23 is the same as that of the color resists 22.

In addition, the thickness of the color resists 20 in the third display sub-area A3 is the same as the thickness of the color resist 20 in the second display sub-area A2, which specifically means that the thickness of the color resists 23 of any color in the third display sub-area A3 is equal to the thickness of the color resists 22 of the same color in the second display sub-area A2. For example, as shown in FIG. 6, the thickness of the first-color color resist 231 is equal to the thickness of the first-color color resist 221, the thickness of the second-color color resist 232 is equal to the thickness of the second-color color resist 222, and the thickness of the third-color color resist 233 is equal to the thickness of the third-color color resist 223.

In this embodiment, the third display sub-area A3 is equivalent to a redundant area similar to the film layer design of the second display sub-area A2, so that the light in the second display sub-area A2 can be prevented from overflowing to the first display sub-area A1, without increasing process difficulty and cost.

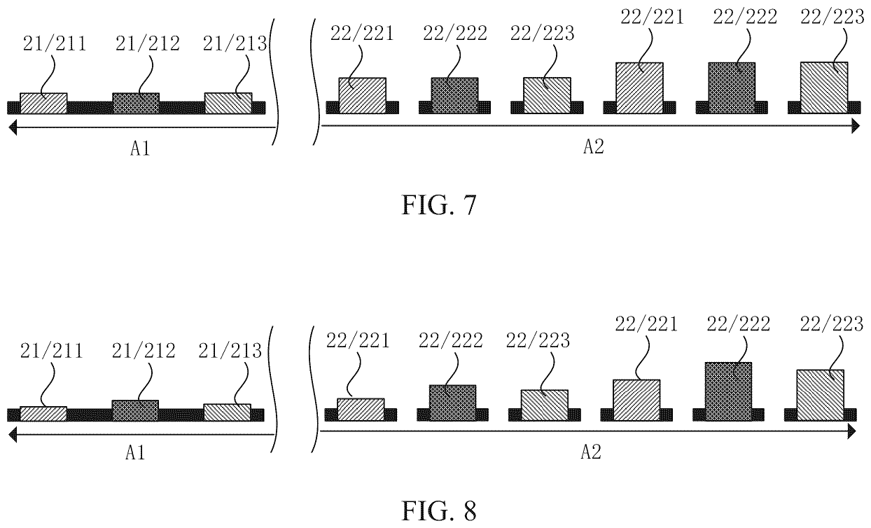

FIG. 7 is a schematic diagram of an arrangement of color resists in a display panel provided by an embodiment of the present disclosure. FIG. 8 is a schematic diagram of an arrangement of color resists in a display panel provided by an embodiment of the present disclosure.

In an embodiment of the present disclosure, as shown in FIG. 7 and FIG. 8, among the color resists 20 of the same color arranged in the second display sub-area A2, thickness of the color resist 20 near the first display sub-area A1 is less than that of the color resist 20 away from the first display sub-area A1. That is, in the second display sub-area A2, the farther the color resist 20 is away from the edge thereof, the larger the thickness of the color resist 20 is, and the nearer the color resist 20 is to the edge thereof, the smaller the thickness of the color resists 20 is.

In an embodiment, as shown in FIG. 7, the color resists 21 of different colors in the first display sub-area A1 have the same thickness. That is, the first-color color resist 211, the second-color color resist 212 and the third-color color resist 213 have the same thickness. In the second display sub-area A2, N adjacent first-color color resists 221, N adjacent second-color color resists 222 and N adjacent third-color color resists 223 constitute one unit. The first-color color resists 221, the second-color color resists 222 and the third-color color resists 223 in each unit have the same thickness. Along a direction from the first display sub-area A1 to the second display sub-area A2, the thickness of the color resists 22 in different units gradually increases.

In an embodiment, as shown in FIG. 8, the color resists 21 of different colors in the first display sub-area A1 have different thicknesses. That is, the thicknesses of the first-color color resist 211, the second-color color resist 212 and the third-color color resist 213 are different from each other. In the second display sub-area A2, along the direction from the first display sub-area A1 to the second display sub-area A2, the thickness of the first-color color resists 221 gradually increases, the thickness of the second-color color resists 222 gradually increases, and the thickness of the third-color color resists 223 gradually increases.

In an embodiment, the thickness of the color resists 20 in the second display sub-area A2 may be configured to be gradually changed. That is, the thickness of the color resist 20 nearer the first display sub-area A1 in the second display sub-area A2 is also closer to the thickness of the color resist 20 in the first display sub-area A1. As a result, it can be ensured that the visual connection between the first display sub-area A1 and the second display sub-area A2 is more natural.

That is, the mitigation of the display difference due to reflectivity difference between the first display sub-area A1 and the second display sub-area A2 can be realized not only by the third display sub-area A3 located between the first display sub-area A1 and the second display sub-area A2, but also by setting the color resists 20 with gradually changed thicknesses inside the second display sub-area A2.

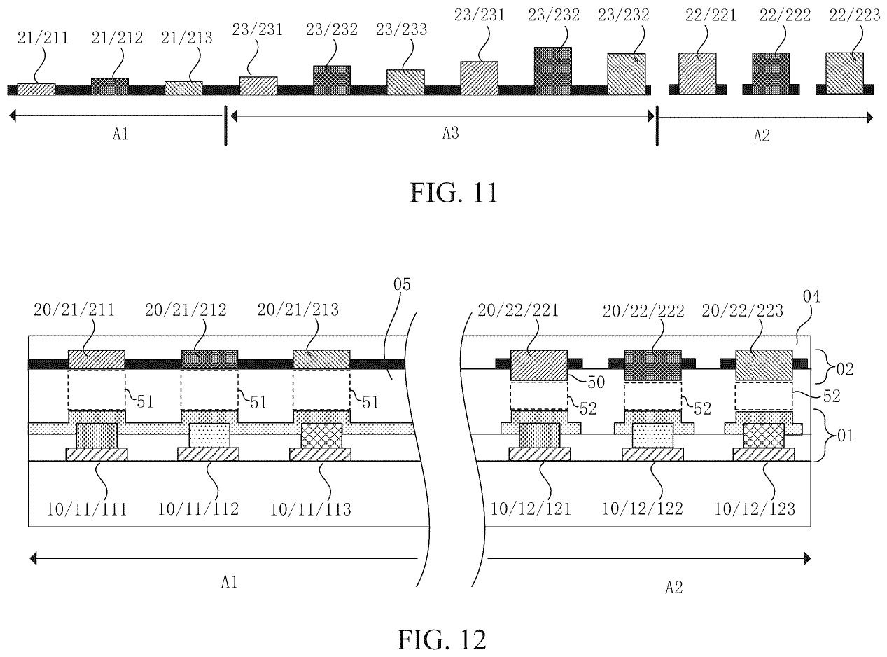

FIG. 9 is a schematic diagram of an arrangement of color resists in a display panel provided by an embodiment of the present disclosure. FIG. 10 is a schematic diagram of an arrangement of color resists in a display panel provided by an embodiment of the present disclosure. FIG. 11 is a schematic diagram of an arrangement of color resists in a display panel provided by an embodiment of the present disclosure.

When the display panel 001 includes the third display sub-area A3, and the thickness of the color resists 23 in the third display sub-area A3 is greater than the thickness of the color resists 21 in the first display sub-area A1 and less than the thickness of the color resists 22 in the second display sub-area A2, the thickness of the color resists 23 in the third display sub-area A3 may be as shown in FIG. 9, and color resists 23 of the same color have a fixed thickness; or as shown in FIG. 10 and FIG. 11, the nearer the color resist 23 are to the first display sub-area A1, the smaller the thickness thereof is.

When the color resist 23 in the third display sub-area A3 is nearer to the first display sub-area A1, and the thickness thereof is smaller, the change rule of the thickness of the color resists 23 in the third display sub-area A3 may be consistent with that of the thickness of the color resists 22 in the second display sub-area A2, which will not be repeated hereinafter.

FIG. 12 is a partial cross-sectional view of a display panel provided by an embodiment of the present disclosure.

In an embodiment of the present disclosure, as shown in FIG. 12, the upper surface of at least part of the color resists 22 in the second display sub-area A2 is flush with that of the color resists 21 in the first display sub-area A1. That is, the surface of at least part of the color resists 22 in the second display sub-area A2 facing the light-emitting surface of the display panel 001 is flush with that of the color resists 21 in the first display sub-area A1 facing the light-emitting surface of the display panel 001.

Upper surfaces of the color resists 22 of at least one color in the second display sub-area A2 are flush with that of the color resists 21 of the same color in the first display sub-area A1. For example, as shown in FIG. 12, the upper surface of the first-color color resist 221 is flush with the upper surface of the first-color color resist 211, the upper surface of the second-color color resist 222 is flush with the upper surface of the second-color color resist 212, and the upper surface of the third-color color resist 223 is flush with the upper surface of the third-color color resist 213.

An insulating layer 04 having a protective effect is usually provided above the color resist layer 02. The upper surface of at least part of the color resists 22 in the second display sub-area A2 is configured to be flush with the that of the color resists 21 in the first display sub-area A1, so that the insulating layer 04 may have a thickness that is as uniform as possible and have a upper surface as flat as possible. If the upper surface of the organic layer is not flat, the light emitted by the light-emitting devices 10 in the light-emitting device layer 01 will scatter when exiting from the upper surface of the insulating layer 04, and rainbow stripes will occur when serious. In this implementation, the upper surface of at least part of the color resists in the second display sub-area A2 is flush with that of the color resists in the first display sub-area Al, so that the upper surface of the insulating layer 04 in the second display sub-area A2 and the first display sub-area A1 is as flat as possible, thereby avoiding problems of rainbow stripes and color dispersion.

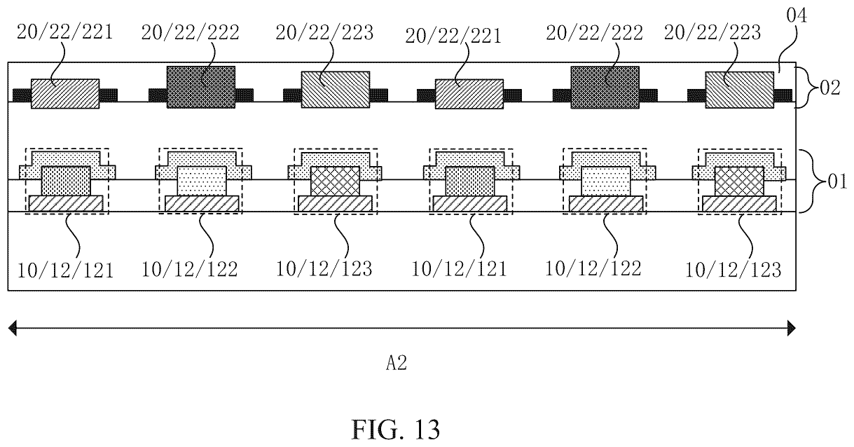

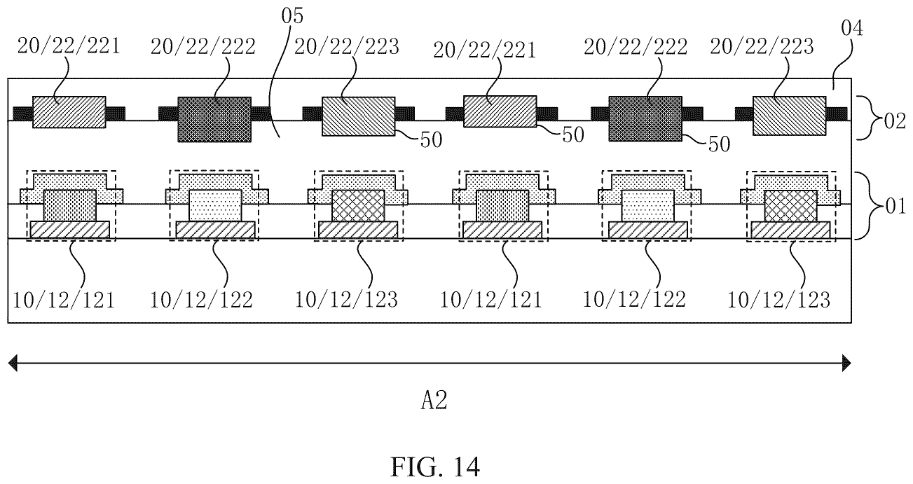

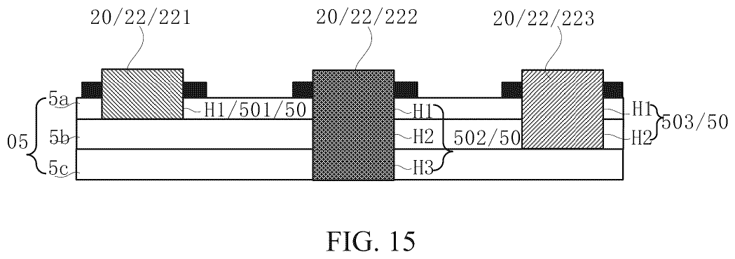

FIG. 13 is a schematic partial cross-sectional view of a second display sub-area in a display panel provided by an embodiment of the present disclosure. FIG. 14 is a schematic partial cross-sectional view of a second display sub-area in a display panel provided by an embodiment of the present disclosure.

In an embodiment of the present disclosure, as shown in FIG. 13 and FIG. 14, the upper surfaces of the color resists 22 of the same color in the second display sub-area A2 are flush with each other. The upper surfaces of all the first-color color resists 221 are flush with each other. The upper surfaces of all the second-color color resists 222 are flush with each other. The upper surfaces of all the third-color color resists 223 are flush with each other.

In an embodiment, as shown in FIG. 13, the upper surfaces of the color resists 22 of the same color in the second display sub-area A2 are flush with each other, and the upper surfaces of the color resists 22 of at least two colors may not be flush with each other. For example, as shown in FIG. 13, the thicknesses of all the first-color color resists 221 are equal to each other, the thicknesses of all the second-color color resists 222 are equal to each other, and the thicknesses of all the third-color color resists 223 are equal to each other. The thickness of the first-color color resists 221, the thickness of the second-color color resists 222 and the thickness of the third-color color resists 223 are different from each other. This implementation is applicable to the condition in which the thicknesses of the color resists 20 of at least two colors are different from each other.

In an embodiment, as shown in FIG. 14, the upper surfaces of all the color resists 22 in the second display sub-area A2 are flush with each other. That is, the upper surface of the first-color color resist 221, the upper surface of the second-color color resist 222 and the upper surface of the third-color color resist 223 are flush with each other. This implementation is applicable to the condition in which the thicknesses of the first-color color resist 221, the second-color color resist 222 and the third-color color resist 223 are different from or the same with each other.

An insulating layer 04 having a protective effect is usually provided above the color resist layer 02. The upper surfaces of the color resists 22 in the second display sub-area A2 are configured to be flush with the upper surfaces of the color resists 21 in the first display sub-area A1, so that the insulating layer 04 can have a uniform thickness and a flat upper surface. If the upper surface of the organic layer is not flat, the light emitted by the light-emitting devices 10 in the light-emitting device layer 01 will scatter when exiting from the upper surface of the insulating layer 04, and rainbow stripes will occur when serious. In this implementation, the upper surfaces of all the color resists in the second display sub-area A2 are flush with each other, such that the upper surface of the insulating layer 04 in the first display area A1 and the second display sub-area A2 can be completely flat, thereby avoiding the problem of rainbow stripes and color dispersion more effectively.

In addition, when the display panel 001 includes the third display sub-area A3, and the thickness of the color resists 23 in the third display sub-area A3 is greater than the thickness of the color resists 21 in the first display sub-area A1, the upper surfaces of the color resists 23 in the third display sub-area A3 may have the same configuration concept as the upper surfaces of the color resists 22 in the second display sub-area A2, which will not be repeated hereinafter.

In an embodiment of the present disclosure, as shown in FIG. 12, the display area further includes an auxiliary layer 05. The auxiliary layer 05 is provided between the light-emitting device layer 01 and the color resist layer 02. The auxiliary layer 05 may be specifically a transparent insulating layer.

In the first display sub-area A1, a portion of the auxiliary layer 05 below the color resists 21 is the first portion 51. In the second display sub-area A2, a portion of the auxiliary layer 05 below the color resists 22 is the second portion 52. The first portion 51 and the second portion 52 are portions of the auxiliary layer 05 in different areas, respectively. In an embodiment of the present disclosure, a thickness of the first portion 51 is greater than a thickness of at least part of the second portion 52.

That is, the surface of at least part of the second portion 52 facing the color resists 22 is lower than the surface of the first portion 51 facing the color resists 21. As a result, the lower surface of the color resists 22 above this part of the second portion 52 may be lower than the lower surface of the color resists 21, which is beneficial to realizing that the thickness of the color resists 22 in the second display sub-area A2 is greater than the thickness of the color resists 21 in the first display area A1.

Meanwhile, it can also be realized that the thickness of the color resists 22 is greater than the thickness of the color resists 21, and the upper surfaces of the color resists 22 are flush with the upper surfaces of the color resists 21, thereby avoiding the phenomena of color dispersion and rainbow stripes.

In addition, in an embodiment, in order to achieve that the thickness of the color resists 22 in the second display sub-area A2 is greater than the thickness of the color resists 21 in the first display area A1, the color resists 22 in the second display sub-area A2 may be extended towards the light-emitting device layer 01, and the color resists with increased thickness are nearer to the corresponding light-emitting devices 10, which is beneficial to increasing the light receiving ability of the color resists 22 to the light emitted by the corresponding light-emitting devices 10, thereby preventing light of different colors from entering between the color resists 22 and the corresponding light-emitting devices 10 to cause light crosstalk.

Moreover, by extending the color resists 22 in the second display sub-area A2 towards the light-emitting device layer 01 to increase the thickness of the color resists 22 in the second display sub-area A2, the increased thickness of the color resists 22 in the second display sub-area A2 does not cause the thickness of the display panel 001 to be increased, which is beneficial to implementing a light and thin display panel 001.

It should be noted that, when the thickness of the color resists 22 is increased by extending the color resists 22 towards the auxiliary layer 05, the auxiliary layer 05 overlaps with the color resist layer along the direction perpendicular to the plane where the display panel 001 is located.

For the convenience of explanation, the following will take the example where the upper surfaces of all the color resists 22 in the second display sub-area A2 are flush with each other for illustration. In addition, when the display panel 001 includes the third display sub-area A3, and the thickness of the color resists 23 in the third display sub-area A3 is different from the thickness of the color resists 21 in the first display sub-area A1, the arrangement of the auxiliary layer 05 in the third display sub-area A3 may refer to the arrangement of the auxiliary layer 05 in the second display sub-area A2, which will not be repeated hereinafter.

In an embodiment, the portion of the auxiliary layer 05 located in the second display sub-area A2 includes a plurality of groove structures 50 facing the color resist layer 02. At least part of the color resists 22 located in the second display sub-area A2 is filled in the groove structures 50. As shown in FIG. 12, the portions of the auxiliary layer 05 located below the color resists 22 in the second display sub-area A2 are all the groove structures 50, and the color resists 22 in the second display sub-area A2 are all filled in the groove structures 50.

In an embodiment, the groove structures 50 for accommodating the color resists 22 are provided in the auxiliary layer 05 in the second display sub-area A2, such that at least part of the color resists 22 in the second display sub-area A2 is designed to be sunken relative to the color resists 21 in the first display sub-area A1. Therefore, it is easy to adjust the flushing degree between the upper surfaces of the color resists 22 in the second display sub-area A2 and the upper surfaces of the color resists in the first display sub-area A1. In addition, the depth of the groove structures 50 is adjustable in the auxiliary layer 05, such that the depth of the groove structures 50 may be configured according to the thickness of the color resists 22 to be accommodated by the groove structure 50. In addition, in an embodiment, the design of the groove structures 50 makes it easy to implement that the upper surfaces of the color resists 22 of different thicknesses in the second display sub-area A2 are flush with each other.

In an embodiment, as shown in FIG. 12, in the second display sub-area A2, all the groove structures 50 have the same depth. In this case, the groove structures 50 may be formed in the same process using the same mask plate, so as to save time and material costs without increasing design difficulty.

In an embodiment, as shown in FIG. 14, in the second display sub-area A2, the auxiliary layer 05 includes a plurality of groove structures 50 having different depths. This technical solution is applicable to the conditions in which the color resists 22 of different colors in the second display sub-area A2 have different thicknesses, and also to the conditions in which the color resists 22 of the same color in the second display sub-area A2 have different thicknesses.

In an embodiment of the present disclosure, as shown in FIG. 14, the light-emitting devices 10 in the light-emitting device layer 01 include a first color light-emitting device 121 and a second color light-emitting device 122. The color resists 20 in the color resist layer 02 include a first-color color resist 221 and a second-color color resist 222. The first-color color resist 221 is provided at a side of the first color light-emitting device 121 facing the light-emitting surface of the display panel 001, The second-color color resist 222 is provided at a side of the second color light-emitting device 122 facing the light-emitting surface of the display panel 001. In an embodiment of the present disclosure, the light-emitting efficiency of the first color light-emitting device 121 is less than that of the second color light-emitting device 122. As a result, in the second display sub-area A2, the thickness of the first-color color resist 221 is less than that of the second-color color resist 222.

In an embodiment, since the light-emitting efficiency of the first color light-emitting device 121 is less than that of the second color light-emitting device 122, the light-emitting brightness of the first color light-emitting device 121 is generally less than that of the second color light-emitting device 122. While since the thickness of the first-color color resist 221 is less than that of the second-color color resist 222, the light transmittance of the first-color color resist 221 is greater than that of the second-color color resist 222. That is, the first-color color resist 221 having the relatively high light transmittance is arranged above the first color light-emitting device 121 having the relatively low light-emitting brightness, and the second-color color resist 222 having the relatively low light transmittance is arranged above the second color light-emitting device 122 having the relatively high light-emitting brightness. Thus, the light-emitting brightness of the first color sub-pixel and the second color sub-pixel can be balanced.

It should be noted that, in this embodiment, by taking the light-emitting devices of different colors in the second display sub-area A2 as an example, the relationship between the light-emitting efficiency of the light-emitting device and the arrangement of respective color resist is described. However, the relationship between the light-emitting efficiency of the light-emitting device and the arrangement of respective color resist in this embodiment are not limited to the light-emitting devices and the color resists in the second display sub-area A2. The corresponding relationship between the light-emitting efficiency of the light-emitting devices and the arrangement of color resists in other areas also satisfies the descriptions of the contexts in the present embodiment.

In an embodiment of the present disclosure, as shown in FIG. 14, the depth of the groove structure 50 filled with the first-color color resist 221 is less than the depth of the groove structure 50 filled with the second-color color resist 222. That is, the second-color color resist 222 having a larger thickness is filled in the groove structure 50 having a deeper depth, and the first-color color resist 221 having a smaller thickness is filled in the groove structure 50 having a lighter depth.

In this implementation, the upper surface of the first-color color resist 221 tends to be flush with or is completely flush with that of the second-color color resist 222, thereby avoiding the problems of rainbow stripes and color dispersion.

In an embodiment, as shown in FIG. 14, the light-emitting devices 10 in the light-emitting device layer 01 further include a third color light-emitting device 123. The color resists 20 in the color resist layer 02 further include a third-color color resist 223. The third-color color resist 223 is provided at a side of the third color light-emitting device 123 facing the light-emitting surface of the display panel 001. In an embodiment, the light-emitting efficiency of the third color light-emitting device 123 is greater than that of the first color light-emitting device 121 and less than that of the second color light-emitting device 122. As a result, in the second display sub-area A2, the thickness of the third-color color resist 223 is less than that of the second-color color resist 222 and greater than that of the first-color color resist 221.

In an embodiment, the light-emitting efficiency of the third color light-emitting device 123 is between the light-emitting efficiency of the first color light-emitting device 121 and the light-emitting efficiency of the second color light-emitting device 122, and the thickness of the third-color color resist 223 is between the thickness of the first-color color resist 221 and the thickness of the second-color color resist 222, which can balance the light-emitting brightness of the first color sub-pixel, the second color sub-pixel and the third color sub-pixel.

In an embodiment, as shown in FIG. 14, the depth of the groove structure 50 filled with the third-color color resist 223 is less than that of the groove structure 50 filled with the second-color color resist 222 and greater than that of the groove structure 50 filled with the first-color color resist 221. The thickness of the third-color color resist 223 is between the thickness of the first-color color resist 221 and the thickness of the second-color color resist 222. The depth of the groove structure 50 filled with the third-color color resist 223 is also between the depth of the groove structure 50 filled with the first-color color resist 221 and the depth of the groove structure 50 filled with the second-color color resist 222.

In this implementation, the upper surface of the first-color color resist 221, the upper surface of the second-color color resist 222, and the upper surface of the third-color color resist 223 tend to be flush or are completely flush with each other, thereby avoiding problems of rainbow stripes and color dispersion.

FIG. 15 is a schematic structural diagram of color resists and an auxiliary layer in a display panel provided by an embodiment of the present disclosure.

In an embodiment of the present disclosure, as shown in FIG. 15, the auxiliary layer 05 includes a first insulating sub-layer 5a, a second insulating sub-layer 5b and a third insulating sub-layer 5c. The first insulating sub-layer 5a is provided at a side of the second insulating sub-CLEAN layer 5b away from the color resist layer 02. The third insulating sub-layer 5c is provided at a side of the second insulating sub-layer 5b facing the light-emitting device layer 01. The first insulating sub-layer 5a includes a first hollow portion H1. The second insulating sub-layer 5b includes a second hollow portion H2. The third insulating sub-layer 5c includes a third hollow portion H3.

In an embodiment of the present disclosure, the groove structure 50 filled with the first-color color resist 221 is the first groove structure 501, the groove structure 50 filled with the second-color color resist 222 is the second groove structure 502, and the groove structure 50 filled with the third-color color resist 223 is the third groove structure 503. The first groove structure 501 includes a first hollow portion H1. The second groove structure 502 includes a first hollow portion H1, a second hollow portion H2, and a third hollow portion H3 that are stacked with each other. The third groove structure 503 includes a first hollow portion H1 and a second hollow portion H2 that are stacked with each other. That is, the first groove structure 501 includes a first hollow portion H1 penetrating the first insulating layer 5a, and the second groove structure 502 includes a first hollow portion H1, a second hollow portion H2, and a third hollow portion H3 that penetrate the first insulating layer 5a, the second insulating layer 5b, and the third insulating layer 5c, respectively.

In an embodiment, by setting the number of insulating layers penetrated by the hollow portions included in the groove structure 50, a plurality of groove structures 50 with various depths can be obtained.

In an embodiment, when the light-emitting efficiency of the third color light-emitting device 123 is between the light-emitting efficiency of the first color light-emitting device 121 and the light-emitting efficiency of the second color light-emitting device 122, and the light-emitting efficiency of the first color light-emitting device 121 is lower than the light-that of the second color light-emitting device 122, it can be seen from the analysis of previous embodiments that the thickness of the first-color color resist 221, the thickness of the third-color color resist 223 and the thickness of the second-color color resist 222 should be designed to be sequentially increased. The depth of the groove structure 50 filled with the first-color color resist 221, the depth of the groove structure 50 filled with the third-color color resist 223 and the depth of the groove structure 50 filled with the second-color color resist 222 should be sequentially increased. In this case, the first-color color resist 221, the third-color color resist 223 and the second-color color resist 222 may be respectively filled in the groove structures 50 formed by the penetration of different numbers of hollow portions, thereby realizing that the upper surfaces of the color resists 22 of three colors tend to be flush or are completely flush with each other.

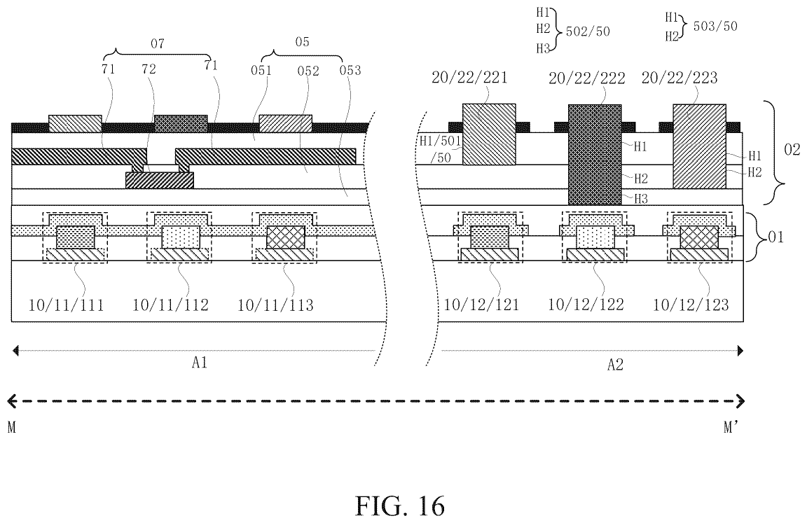

FIG. 16 is a partial cross-sectional view of a display panel provided by an embodiment of the present disclosure.

In an embodiment of the present disclosure, as shown in FIG. 16, the display panel 001 includes a touch layer 07 provided between the color resist layer 02 and the light-emitting device layer 01. The auxiliary layer 05 is arranged adjacent to the touch layer 07.

In an embodiment, the touch layer 07 includes a first touch conductive layer 71. The auxiliary layer 05 includes a first auxiliary sub-layer 051 provided between the first touch conductive layer 71 and the color resist layer 02. In an embodiment, at least part of the groove structures 50 penetrate through the first auxiliary sub-layer 051.

For example, as shown in FIG. 16, the first auxiliary sub-layer 051 is provided at a side of the touch layer 07 away from the light-emitting device layer 01. The first auxiliary sub-layer 051 includes a first hollow portion H1. The groove structure 50 includes a first hollow portion H1.

In addition, the touch layer 07 further includes a second touch conductive layer 72 provided at a side of the first touch conductive layer 71 near the light-emitting device layer 01. The auxiliary layer 05 includes a second auxiliary sub-layer 052 provided between the first touch conductive layer 71 and the second touch conductive layer 72. In an embodiment, at least part of the groove structures 50 penetrates the first auxiliary sub-layer 051 and the second auxiliary sub-layer 052.

For example, as shown in FIG. 16, the groove structures 50 includes a first groove structure 501 filled with the first-color color resist 221, a second groove structure 502 filled with the second-color color resist 222, and a third groove structure 503 filled with the third-color color resist 223. The depth of the second groove structure 502 and the depth of the third groove structure 503 are both greater than the depth of the first groove structure 501. In an embodiment, the second auxiliary sub-layer 052 may include a second hollow portion H2. The second groove structure 502 may include a first hollow portion H1 and a second hollow portion H2 that are penetrating. The third groove structure 503 may also include a first hollow portion H1 and a second hollow portion H2 that are penetrating. The first groove structure 501 does not include a second hollow portion H2.

One of the first touch conductive layer 71 and the second touch conductive layer 72 may include touch electrodes, and the other may include a cross-bridge electrode, the cross-bridge electrode is configured to electrically connect two touch electrodes. In addition, the via hole required for connecting the cross-bridge electrode and the touch electrode may be formed simultaneously with the hollow portion in the auxiliary layer. For example, the second auxiliary sub-layer 052 is provided between the first touch conductive layer 71 and the second touch conductive layer 72, the via hole required for connecting the cross-bridge electrode and the touch electrode may be formed simultaneously with the second hollow portion H2 in the second auxiliary sub-layer 052.

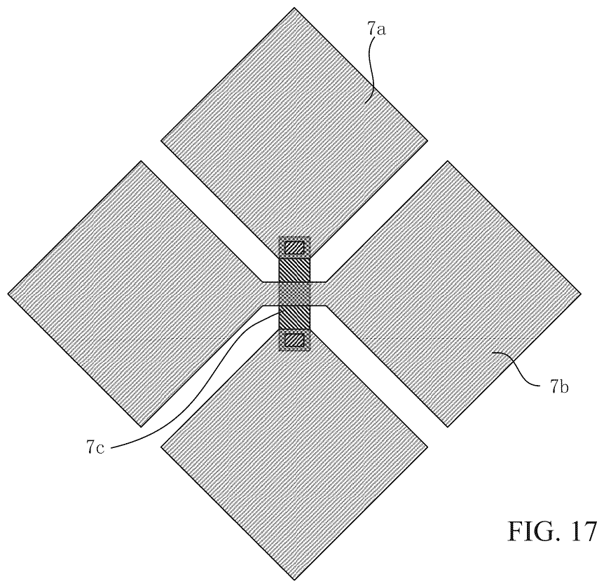

FIG. 17 is a schematic projection diagram of a touch layer in a display panel provided by an embodiment of the present disclosure.

For example, referring to FIG. 16 and FIG. 17, the first touch conductive layer 71 includes a first touch electrode 7a and a second touch electrode 7b. One of the first touch electrode 7a and the second touch electrode 7b may be a touch driving electrode and the other may be a touch sensing electrode. The first touch electrode 7a is electrically insulated from the second touch electrode 7b.

As shown in FIG. 16 and FIG. 17, the first touch electrode 7a intersects with the second touch electrode 7b. In order to realize electrical insulation between the first touch electrode 7a and the second touch electrode 7b, the portions of the first touch electrode 7a located at two sides of the second touch electrode 7b may be electrically connected to each other through the cross-bridge electrode 7c in a layer different from the layer where the first touch conductive layer 71 is located. That is, the second touch conductive layer 72 includes the cross-bridge electrode 7c. The first touch electrode 7a and the second touch electrode 7b are electrically connected to each other at the cross position thereof through the cross-bridge electrode 7c.

In addition, in another embodiment, the touch layer 07 may include only one touch conductive layer.

In an embodiment, when the touch layer 07 includes only one touch conductive layer, the touch electrodes included therein are in a self-capacitance mode.

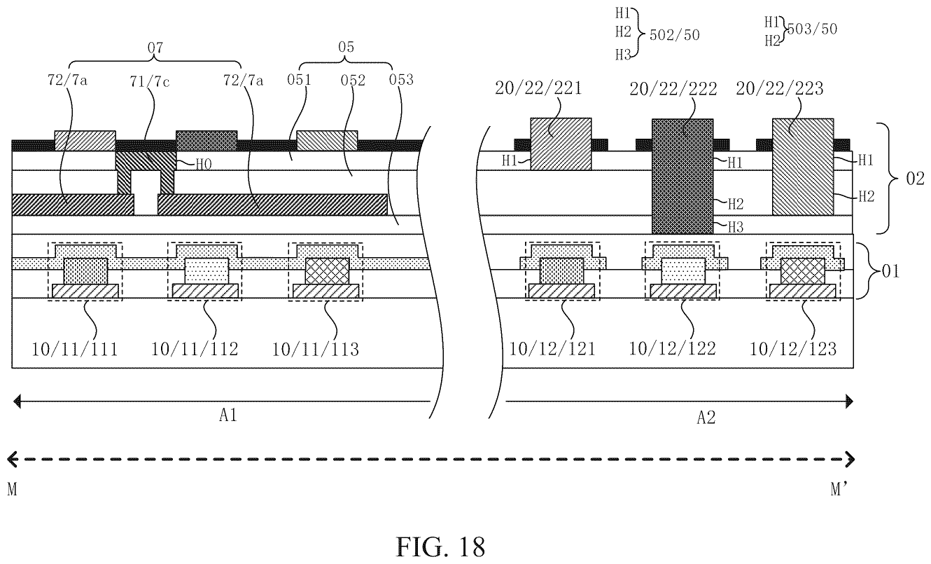

FIG. 18 is a partial cross-sectional view of a display panel provided by an embodiment of the present disclosure.

In addition, as shown in FIG. 18, the first touch conductive layer 71 includes a cross-bridge electrode 7c, and the second touch conductive layer includes touch electrodes 7a. The cross-bridge electrode electrically connects two adjacent touch electrodes 7a. The first auxiliary sub-layer 051 and/or the second auxiliary sub-layer 052 includes a hollow structure H0. The cross-bridge electrode 7c is provided in the hollow structure H0.

Since the first auxiliary sub-layer 051 and the second auxiliary sub-layer 052 need to be provided with a hollow portion forming a groove structure, the hollow structure H0 for accommodating the cross-bridge electrode 7c may be formed simultaneously with at least one hollow portion forming the groove structure. For example, as shown in FIG. 18, the first auxiliary sub-layer 051 includes a hollow structure H0, and the cross-bridge electrode 7c is provided in the hollow structure H0. In this case, the hollow structure H0 for accommodating the cross-bridge electrode 7c may be formed simultaneously with the first hollow portion H1, and the via hole penetrating the second auxiliary sub-layer 052 when the cross-bridge electrode 7c electrically connects with the touch electrodes 7a may also be formed simultaneously with the second hollow portion H2 in the second auxiliary sub-layer 052.

Further, the auxiliary layer 05 includes a third auxiliary sub-layer 053 provided at a side of the touch layer 07 away from the color resist layer 02. In an embodiment, at least part of the groove structures 50 penetrates the first auxiliary sub-layer 051, the second auxiliary sub-layer 052 and the third auxiliary sub-layer 053.

For example, as shown in FIG. 16, the depth of the second groove structure 502 is greater than that of the third groove structure 503 and greater than that of the first groove structure 501. In an embodiment, the third auxiliary sub-layer 053 may include a third hollow portion H3. The second groove structure 502 may include a first hollow portion H1, a second hollow portion H2, and a third hollow portion H3 that are penetrating, and neither the third groove structure 503 nor the first groove structure 501 includes a third hollow portion H3.

When the display panel 001 includes the touch layer 07, respective insulating layers will be provided to isolate the touch layer 07 from other functional film layers, and/or isolate different conductive layers in the touch layer 07. These insulating layers are referred to as touch insulating layers. In an embodiment of the present disclosure, the touch insulating layers located in the second display sub-area A2 are reserved, and the touch insulating layers may be reused as auxiliary layers for providing hollow portions to form the groove structures. In an aspect, the process of removing the touch insulating layers in the second display sub-area A2 is simplified. In another aspect, it is possible to avoid increasing the thickness of the display panel 001 due to adding an additional auxiliary film layer. Furthermore, since the display panel 001 includes at least two touch insulating layers, different depths of different groove structures for accommodating different color resists 20 can be achieved by selecting the number of touch insulating layers provided with hollow portions.

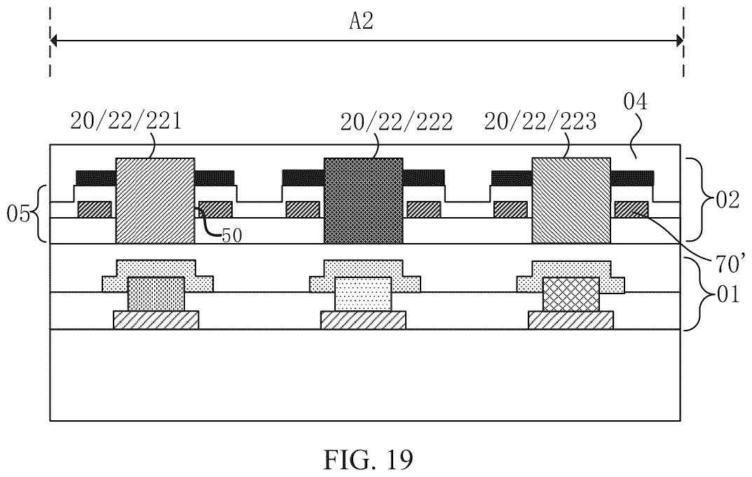

FIG. 19 is a partial cross-sectional view of a second display sub-area in a display panel provided by an embodiment of the present disclosure.

In an embodiment of the present disclosure, as shown in FIG. 19, the second display sub-area A2 further includes a metal cushion layer provided adjacent to the auxiliary layer 05. The metal cushion layer includes metal pads 70′ provided at the periphery of the groove structures 50. As shown in FIG. 19, the auxiliary layer 05 wraps the metal pads 70′. Further, the auxiliary layer 05 may also be provided above the metal cushion layer and cover the metal pads 70′.

In an embodiment, since the metal pads 70′ are provided at the periphery of the groove structures 50 of the auxiliary layer 05, in the second display sub-area A2, along the direction perpendicular to the plane where the display panel is located, the distance between the upper surface of the auxiliary layer 05 on the side of the metal pads 70′ away from the substrate and the substrate is greater than the distance between the upper surface of the auxiliary layer in the area outside the metal pads 70′ and the substrate. That is, the metal pads 70′ raise the height of the auxiliary layer 05 at the periphery of the groove structures 50, which is beneficial to increasing the depth of the groove structures 50, and thus facilitates the color resists 20 in the second display sub-area A2 to have a larger thickness.

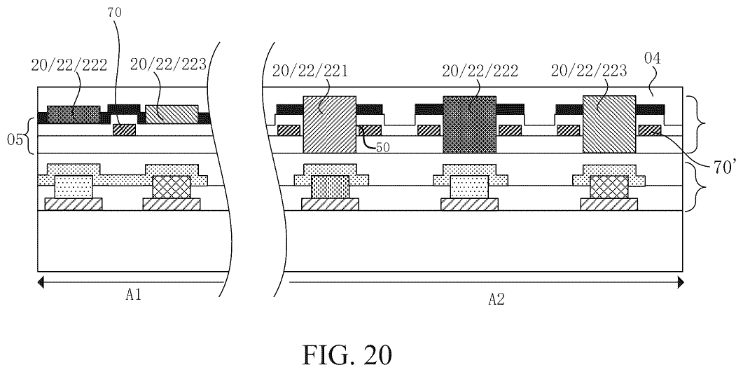

FIG. 20 is a partial cross-sectional view of a display panel provided by an embodiment of the present disclosure.

In an embodiment, the touch layer 07 includes a touch conductive structure 70. The touch conductive structure 70 may be at least one of a touch electrode and a cross-bridge electrode. The metal pads 70′ may be provided in the same layer as at least part of the touch conductive structure 70. That is, the metal pads 70′ may be provided in the same layer as at least one of the touch electrode and the cross-bridge electrode. In this case, the metal pads 70′ may be prepared simultaneously with the touch conductive structure 70. For example, as shown in FIG. 20, the touch conductive structure 70 in the touch layer 07 includes a touch electrode. The metal pads 70′ may be provided in the same layer as the touch electrode. In this case, the metal pads 70′ may be prepared simultaneously with the touch electrode.

In an embodiment, a metal pad 70′ is reused as the touch conductive structure 70. The metal pad 70′ may be used to implement the touch-control function. That is, at least part of the touch conductive structure 70 in the second display sub-area A2 may surround the groove structure 50 to form the metal pad 70′.

The metal pads 70′ may be electrically connected to the touch electrode, and/or the metal pads 70′ may be electrically connected to the cross-bridge electrode. For example, as shown in FIG. 20, when the touch conductive structure 70 in the touch layer 07 includes a touch electrode and does not include a cross-bridge electrode, the metal pads 70′ may be in the same layer as the touch electrode and electrically connected to the touch electrode. For example, when the touch conductive structure 70 in the touch layer 07 includes a touch electrode and a cross-bridge electrode, the metal pads 70′ may be provided in the same layer as the touch electrode and electrically connected to the touch electrode, or the metal pads 70′ may be provided in the same layer as the cross-bridge electrode and electrically connected to the cross-bridge electrode, or a part of the metal pads 70′ may be provided in the same layer as the touch electrode and electrically connected to the touch electrode and a part of the metal pads 70′ may be provided in the same layer as the cross-bridge electrode and electrically connected to the cross-bridge electrode.

In an embodiment, the metal pads 70′ may be electrically insulated from the touch conductive structure 70. The metal pads 70′ may be prepared when the touch conductive structure 70 is manufactured, and may not be configured to implement the touch-control function.

For example, as shown in FIG. 20, when the touch conductive structure 70 in the touch layer 07 includes a touch electrode and does not include a cross-bridge electrode, the metal pads 70′ may be in the same layer as the touch electrode and not electrically connected to the touch electrode. For example, when the touch conductive structure 70 in the touch layer 07 includes a touch electrode and a cross-bridge electrode, the metal pads 70′ may be provided in the same layer as the touch electrode and electrically insulated from the touch electrode, or the metal pads 70′ may be provided in the same layer as the cross-bridge electrode and electrically insulated from the cross-bridge electrode, or a part of the metal pads 70′ may be provided in the same layer as the touch electrode and electrically insulated from the touch electrode and a part of the metal pads 70′ may be provided in the same layer as the cross-bridge electrode and electrically insulated from the cross-bridge electrode.

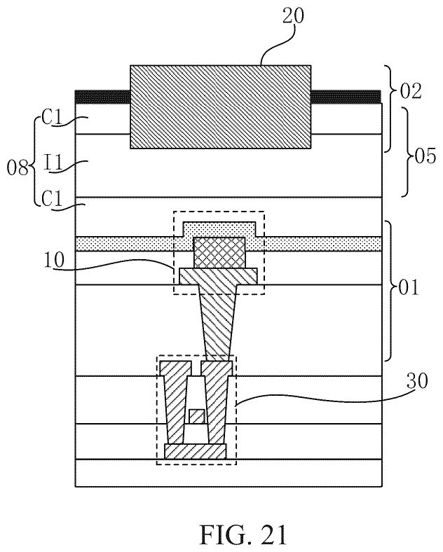

FIG. 21 is a partial cross-sectional view of a display panel provided by an embodiment of the present disclosure.

In an embodiment of the present disclosure, the display panel 001 further includes an encapsulation layer 08 provided between the color resist layer 02 and the light-emitting device layer 01. As shown in FIG. 21, the encapsulation layer 08 may include two inorganic layers C1 and an organic layer I1 provided between the two inorganic layers C1. As shown in FIG. 21, the encapsulation layer 08 is reused as at least part of the film layers in the auxiliary layer 05.

In an embodiment, since the organic layer I1 within the encapsulation layer 08 has a relatively large thickness, one film layer in the auxiliary layer 05 may reuse the organic layer I1 of the encapsulation layer 08. In this embodiment, the groove structures 50 with various depths may be obtained by using the organic layer with the larger thickness in the encapsulation layer 08.

In addition, the encapsulation layer 08 may be provided between the touch layer 07 and the light-emitting device layer 01. When the auxiliary layer 05 is adjacent to the touch layer 07, at least part of the film layers in the encapsulation layer 08 may be reused as the film layers in the auxiliary layer 05. Since the thickness of the touch layer 07 and the thickness of the film layer adjacent thereto are usually relatively thin, when the depth of the groove structure 50 is relatively large, the thickness of the film layer adjacent to the touch layer 07 is not able to reach the required depth of the groove structures 50. Therefore, the auxiliary layer 05 may reuse part of the film layers in the encapsulation layer 08.

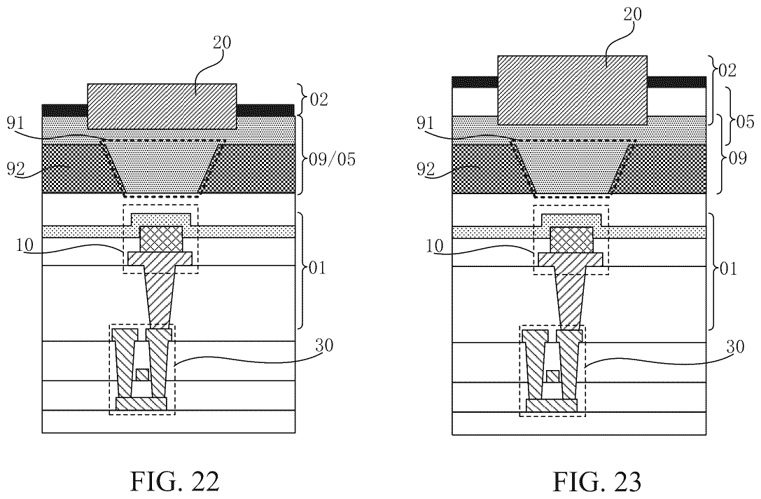

FIG. 22 is a schematic partial cross-sectional view of a display panel provided by an embodiment of the present disclosure. FIG. 23 is a schematic partial cross-sectional view of a display panel provided by an embodiment of the present disclosure.

In an embodiment of the present disclosure, as shown in FIG. 22 and FIG. 23, the display panel 001 further includes a light extraction structure layer 09 provided between the color resist layer 02 and the light-emitting device layer 01. The light extraction structure layer 09 includes light extraction structures 91 and peripheral structures 92. the peripheral structure 92 surrounds the light extraction structure 91. A refractive index of the peripheral structure 92 is less than a refractive index of the light extraction structure 91. Accordingly, an interface between the light extraction structure 91 and the peripheral structure 92 surrounding the light extraction structure 91 is an interface between an optically dense medium and an optically sparse medium. The light extraction structure 91 is provided at a side of the light-emitting device 10 facing the light-emitting surface. The light extraction structure 91 includes an inclined sidewall. In this case, the light extraction structure 91 may convert large-angle light emitted by the light-emitting device 10 therebelow into small-angle light to be emitted, thereby increasing the brightness of the sub-pixel.

In an embodiment, the light extraction structure layer 09 is reused as at least part of the film layers of the auxiliary layer 05. For example, as shown in FIG. 22, the film layer where the light extraction structure 91 is located in the light extraction structure layer 09 is reused as the auxiliary layer 05.

In an embodiment, the auxiliary layer 05 is provided adjacent to the light extraction structure layer 09. In addition, when the depth of the groove structure 50 in the auxiliary layer 05 is relatively deep, as shown in FIG. 23, the light extraction structure layer 09 is reused as a part of the film layers in the auxiliary layer 05.

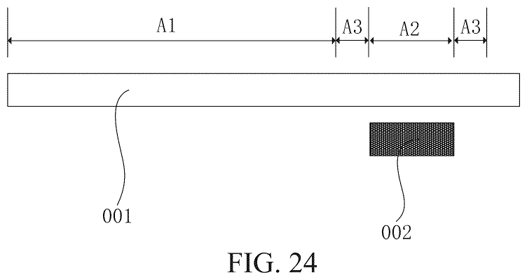

FIG. 24 is a schematic diagram of a display device provided by an embodiment of the present disclosure.

An embodiment of the present disclosure further provides a display device. As shown in FIG. 24, the display device provided by the embodiment of the present disclosure may include the display panel 001 according to any one of above embodiments. The display device provided by the embodiment of the present disclosure may be a mobile phone. In addition, the display device provided by the embodiment of the present disclosure may also be a display device such as a computer or a television.

As shown in FIG. 24, the display device provided by the embodiment of the present disclosure further includes an optical functional element 002. The optical functional element 002 is provided at a position of the display device corresponding to the second display sub-area A1 of the display panel 001. That is, along the direction perpendicular to the plane in which the display panel 001 is located, the optical functional element 002 is provided below the second display sub-area A1 of the display panel 001. In this case, the optical functional element 002 may emit light to the side of the light-emitting surface of the display panel 001 through the second display sub-area A1, and/or may receive light from the side of the light-emitting surface of the display panel 001 through the second display sub-area A1.

The optical functional element 002 is at least one of an optical fingerprint sensor, an iris identification sensor, and a camera.

In an embodiment of the present disclosure, the thickness of at least part of the color resists 20 in the second display sub-area A2 is controlled to be greater than the thickness of the color resists 20 in the first display sub-area A1, such that the transmittance of the color resists 20 in the second display sub-area A2 to external light can be reduced, thereby reducing the light emitted through the color resists 20 into the film layer in which the light-emitting device 10 is located and the film layer in which the pixel circuits are located in the display panel 001. That is, by setting larger thickness of the color resists 20 in the second display sub-area A2, the amount of light that can be reflected in the second display sub-area A2 is reduced, thereby realizing that the reflectivity of the sub-pixel area in the second display sub-area A2 to the external light can be smaller than the reflectivity of the sub-pixel area in the first display sub-area A1 to the external light. Therefore, in an embodiment of the present disclosure, the reflectivity difference between the second display sub-area A2 and the first display sub-area A1 is reduced, which ensures the display uniformity of the display device, and avoids the problem that the second display sub-area A2 is obviously visible due to the large reflectivity difference between the second display sub-area A2 and the first display sub-area A1.

The above descriptions are merely preferred embodiments of the present disclosure and are not intended to limit the present disclosure. It should be noted that any modifications, equivalent substitutions, improvements, and the like made within the spirit and principle of the present disclosure shall fall within the protection scope of the present disclosure.

1. A display panel comprising a display area, wherein the display area comprises a first display sub-area and a second display sub-area, and the second display sub-area comprises a light-transmitting area;
the display area comprises a light-emitting device layer and a color resist layer, the light-emitting device layer comprises a plurality of light-emitting devices, the color resist layer comprises a plurality of color resists, and color resists of the plurality of color resists are provided at a side of the light-emitting devices facing a light-emitting surface of the display panel; and
wherein a thickness of at least part of color resists of the plurality of color resists in the second display sub-area is greater than thicknesses of color resists of the plurality of color resists in the first display sub-area.

2. The display panel according to claim 1, wherein an upper surface of at least part of color resists of the plurality of color resists in the second display sub-area is flush with an upper surface of color resists of the plurality of color resists in the first display sub-area.

3. The display panel according to claim 1, wherein the display area further comprises a third display sub-area, the third display sub-area is located between the first display sub-area and the second display sub-area, and light transmittance of the third display sub-area is less than light transmittance of the second display sub-area; and
thicknesses of color resists in the third display sub-area are greater than thicknesses of the color resists in the first display sub-area and less than thicknesses of the color resists in the second display sub-area.

4. The display panel according to claim 1, wherein the display area further comprises a third display sub-area, the third display sub-area is located between the first display sub-area and the second display sub-area, and light transmittance of the third display sub-area is less than light transmittance of the second display sub-area; and
thicknesses of color resists in the third display sub-area are the same as thicknesses of the color resists in the second display sub-area.

5. The display panel according to claim 1, wherein, among color resists of a same color provided in the second display sub-area, a thickness of a color resist near the first display sub-area is less than a thickness of a color resist away from the first display sub-area.

6. The display panel according to claim 1, wherein the display area further comprises an auxiliary layer located between the light-emitting device layer and the color resist layer;
a portion of the auxiliary layer below the color resists in the first display sub-area is a first portion, and a portion of the auxiliary layer below the color resists in the second display sub-area is a second portion; and
a thickness of the first portion is greater than a thickness of at least part of the second portion.

7. The display panel according to claim 6, wherein the portion of the auxiliary layer located in the second display sub-area comprises a plurality of groove structures facing the color resist layer, and groove structures of the plurality of groove structures are filled with the color resists located in the second display sub-area.

8. The display panel according to claim 7, wherein the groove structures comprise a same depth.

9. The display panel according to claim 7, wherein the plurality of light-emitting devices in the light-emitting device layer comprises a first color light-emitting device and a second color light-emitting device, the plurality of color resists in the color resist layer comprise a first-color color resist and a second-color color resist, the first-color color resist is located at a side of the first color light-emitting device facing the light-emitting surface of the display panel, and the second-color color resist is located at a side of the second color light-emitting device facing the light-emitting surface of the display panel; and
wherein light-emitting efficiency of the first color light-emitting device is less than light-emitting efficiency of the second color light-emitting device, and in the second display sub-area, a thickness of the first-color color resist is less than a thickness of the second-color color resist.

10. The display panel according to claim 9, wherein a depth of the groove structure filled with the first-color color resist is less than a depth of the groove structure filled with the second-color color resist.

11. The display panel according to claim 9, wherein the plurality of light-emitting devices in the light-emitting device layer further comprises a third color light-emitting device, the plurality of color resists in the color resist layer further comprises a third-color color resist, and the third-color color resist is located at a side of the third color light-emitting device facing the light-emitting surface of the display panel; and
wherein light-emitting efficiency of the third color light-emitting device is greater than light-emitting efficiency of the first color light-emitting device and less than light-emitting efficiency of the second color light-emitting device, and in the second display sub-area, a thickness of the third-color color resist is less than a thickness of the second-color color resist and greater than a thickness of the first-color color resist.

12. The display panel according to claim 11, wherein a depth of the groove structure filled with the third-color color resist is less than a depth of the groove structure filled with the second-color color resist and greater than a depth of the groove structure filled with the first-color color resist.

13. The display panel according to claim 12, wherein the auxiliary layer comprises a first insulating sub-layer, a second insulating sub-layer and a third insulating sub-layer, the first insulating sub-layer is located at a side of the second insulating sub-layer away from the color resist layer, the third insulating sub-layer is located at a side of the second insulating sub-layer facing the light-emitting device layer, the first insulating sub-layer comprises a first hollow portion, the second insulating sub-layer comprises a second hollow portion, and the third insulating sub-layer comprises a third hollow portion; and
wherein the groove structure filled with the first-color color resist is a first groove structure, and the first groove structure comprises the first hollow portion; the groove structure filled with the second-color color resist is a second groove structure, and the second groove structure comprises the first hollow portion, the second hollow portion, and the third hollow portion that overlap each other; and the groove structure filled with the third-color color resist is a third groove structure, and the third groove structure comprises a first hollow portion and a second hollow portion that overlap each other.

14. The display panel according to claim 7, wherein the display panel further comprises a touch layer located between the color resist layer and the light-emitting device layer, and the auxiliary layer is provided adjacent to the touch layer.

15. The display panel according to claim 14, wherein the touch layer comprises a first touch conductive layer; and
the auxiliary layer comprises a first auxiliary sub-layer, the first auxiliary sub-layer is located between the first touch conductive layer and the color resist layer, and at least part of the groove structures penetrates the first auxiliary sub-layer.

16. The display panel according to claim 15, wherein the touch layer further comprises a second touch conductive layer located at a side of the first touch conductive layer away from the color resist layer; and
the auxiliary layer comprises a second auxiliary sub-layer located between the first touch conductive layer and the second touch conductive layer, and at least part of the groove structures penetrates the first auxiliary sub-layer and the second auxiliary sub-layer.

17. The display panel according to claim 16, wherein the first touch conductive layer comprises a cross-bridge electrode, the second touch conductive layer comprises touch electrodes, and the cross-bridge electrode electrically connects two adjacent touch electrodes; and
the first auxiliary sub-layer and/or the second auxiliary sub-layer comprises a hollow structure, and the cross-bridge electrode is provided in the hollow structure.

18. The display panel according to claim 16, wherein the auxiliary layer comprises a third auxiliary sub-layer, and the third auxiliary sub-layer is located at a side of the touch layer away from the color resist layer, and at least part of the groove structures penetrates the first auxiliary sub-layer, the second auxiliary sub-layer and the third auxiliary sub-layer.

19. The display panel according to claim 14, wherein the second display sub-area further comprises a metal pad layer provided adjacent to the auxiliary layer; and
the metal cushion layer comprises a plurality of metal pads, and metal pads of the plurality of metal pads are located at a periphery of the groove structures.

20. The display panel according to claim 19, wherein the touch layer comprises a touch conductive structure; and one of the metal pads is reused as a partial structure of the touch conductive structure.

21. The display panel according to claim 19, wherein the touch layer comprises a touch conductive structure; and the metal pads and the touch conductive structure are provided in a same layer, and the metal pads are electrically insulated from the touch conductive structure.

22. The display panel according to claim 6, wherein the display panel further comprises a light extraction structure layer located between the color resist layer and the light-emitting device layer; and the auxiliary layer is provided adjacent to the light extraction structure layer, and/or the light extraction structure layer is reused as at least part of film layers in the auxiliary layer.

23. The display panel according to claim 6, wherein the display panel further comprises an encapsulation layer located between the color resist layer and the light-emitting device layer, and the encapsulation layer is reused as at least part of the auxiliary layer.

24. A display device comprising a display panel, wherein the display area comprises a first display sub-area and a second display sub-area, and the second display sub-area comprises a light-transmitting area;
the display area comprises a light-emitting device layer and a color resist layer, the light-emitting device layer comprises a plurality of light-emitting devices, the color resist layer comprises a plurality of color resists, and color resists of the plurality color resists are provided at a side of the light-emitting devices facing a light-emitting surface of the display panel; and
wherein a thickness of at least part of the color resists in the second display sub-area is greater than thicknesses of the color resists in the first display sub-area
